(19) United States
(12) Patent Application Publication
(10) Pub. No.: US 2025/0261355 A1
(43) Pub. Date: Aug. 14, 2025

(54) Nanostructured Copper for Electromagnetic Interference Shielding and Method for same

(71) Applicant: The Research Foundation for The State University of New York, Amherst, NY (US)

(72) Inventors: Shenqiang REN, Williamsville, NY (US); Aaron SHENG, Buffalo, NY (US)

(21) Appl. No.: 18/616,065

(22) Filed: Mar. 25, 2024

Related U.S. Application Data
(60) Provisional application No. 63/492,207, filed on Mar. 24, 2023.

(51) Int. Cl. H05K 9/00; C09D 11/03; C09D 11/08; H05K 1/02; H05K 3/12

(52) U.S. Cl. CPC H05K 9/0092; C09D 11/03; C09D 11/08; H05K 1/0224; H05K 3/1283; H05K 2201/0715; H05K 2203/0338; H05K 2203/1131

(57) ABSTRACT

A method of applying an electromagnetic interference (EMI) shield to a substrate includes depositing a layer of ink onto the substrate. The ink contains copper (Cu) nanoplates and a solvent. The solvent is evaporated from the deposited layer, and the deposited layer is sintered to form an EMI shield. In some embodiments, the ink also includes copper nanoparticles and/or copper nanowires. In another aspect, an EMI shield includes a layer of sintered copper nanoplates, and optionally, copper nanoparticles and/or copper nanowires.

### CROSS-REFERENCE TO RELATED APPLICATIONS

This application claims priority to U.S. Provisional Application No. 63/492,207, filed on Mar. 24, 2023, now pending, the disclosure of which is incorporated herein by reference.

### STATEMENT REGARDING FEDERALLY SPONSORED RESEARCH

This invention was made with government support under contract no. W911NF-20-2-0016 awarded by the U.S. Army Research Lab. The government has certain rights in the invention.

### FIELD OF THE DISCLOSURE

The present disclosure relates to the field of electromagnetic interference shielding. More specifically, the disclosure pertains to EMI shielding and techniques for applying an EMI shielding containing copper nanoplates.

### BACKGROUND OF THE DISCLOSURE

Electromagnetic interference (EMI) is a significant concern in various applications, such as electronics, telecommunications, and aerospace. EMI can cause disruptions in the proper functioning of electronic devices, leading to degraded performance or, in some cases, complete device failure. EMI shielding is essential for mitigating these detrimental effects, and a range of shielding methods has been developed over the years.

However, many conventional EMI shielding techniques are time-consuming, expensive, or can result in low-quality shielding. There is a need for a more efficient and cost-effective method of applying EMI shielding to a substrate.

### BRIEF SUMMARY OF THE DISCLOSURE

Printing metallic nanomaterials toward electromagnetic interference shielding is highly desirable, especially with a minimal thickness and mechanical flexibility. The present disclosure describes the geometry and conductivity effects of printed nanostructured copper on the reflection and absorption of electromagnetic interference shielding. The electromagnetic interference shielding is observed to increase as the conductivity increases with an advantageous electromagnetic interference shielding effectiveness of 65 dB, on which a shielding effectiveness diagram is constructed to illustrate the role of electric conductivity and architectures of printed nanostructured copper features. The findings reported here provide insight into printed flexible metallic materials for electromagnetic interference shielding.

### DESCRIPTION OF THE DRAWINGS

For a fuller understanding of the nature and objects of the disclosure, reference should be made to the following detailed description taken in conjunction with the accompanying drawings.

FIG. 1. (a) Schematic of the electromagnetic interference shielding (EMI-SH) process of layered copper nanoplates (Cu NPLs). An incident wave impinges on the sample and there are three possible outcomes: transmission, reflection, and absorption. (b) Graph of EMI-SH vs conductivity of a sample of printed Cu NPLs. The black points are the measured data. The fit line is shown for clarity of the trend.

FIG. 2. (a, left) Various nanostructures resulting from low (Cu nanoparticles (NPs)) to high (Cu NPLs) concentrations of iodide. (a, right) Schematic of a printed sample with the mixture of the Cu nanostructures. (b) Scanning electron microscopy (SEM) image of printed samples of Cu nanostructures synthesized at various I⁻ concentrations. The scale bar represents 10 μm. (c) Related EMI-SH efficiencies of the printed samples in (b).

FIG. 3. (a) SEM images of Cu NPLs (top left), Cu nanowires (NWs) (top right), Cu NPs (bottom left), and 1:1:1 (NPLs:NWs:NPs) mixture (bottom right). The scale bar represents 10 μm. (b) EMI-SH efficiency of Cu NPLs, Cu NWs, and 1:1:1 mixture at similar thicknesses (˜3 μm).

FIG. 4. (a) SEM images of 1:1:0, 1:0:1, and 2:1:1 mixtures (NPLs:NWs:NPs). The scale bar represents 10 μm. (b) EMI-SH efficiencies of various Cu nanostructure mixtures. The mixtures of 0:1:1, 1:2:1, and 1:1:2 have EMI-SH efficiencies overlapped below 5 dB. (c) Ternary EMI-SH plot of all the mixture ratios (including the single nanostructures). The values reported are the values at 13 GHz.

FIG. 5. (a) Infrared spectra of nickel chloride, sodium formate, and nickel formate. (b) Energy dispersive X-ray spectroscopy (EDS) mapping spectra (top) with the copper (red) and nickel (green) overlaid on top. An EDS linescan (bottom) is shown of one Cu NPL. (c) EMI-SH vs conductivity dependence as a function of the concentration of NiF added. (d) Overlaid data of Cu/Ni conductors (circles) with Cu NPL conductors (squares).

FIG. 6. The EMI-SH vs conductivity of Cu NPLs (all collected data). Each recorded thickness has been color-coded. The shape of the data represents either a typical synthesis (circle) or an attempt at larger Cu NPL synthesis (triangle).

FIG. 7. The EMI-SH efficiency vs thickness of Cu NPLs (squares) and Cu/Ni (circles).

FIG. 8. The pXRD diffractogram of printed samples at various iodide concentration.

FIG. 9. EMI-SH data for a printed sample of Cu NPs.

FIG. 10. SEM images for the mixture (NPL:NW:NP) samples with low EMI-SH efficiencies (left: 0:1:1; center: 1:2:1; right: 1:1:2).

FIG. 11. PXRD diffractogram of Cu NPL (grey) and Cu/Ni (orange) printed samples.

FIG. 12. The printed and sintered samples of Cu/Ni with low NiF (left) and high NiF (right) concentrations.

FIG. 13. A chart depicting a method according to an embodiment of the disclosure.

### DETAILED DESCRIPTION OF THE DISCLOSURE

Advancements in electronics are advancing rapidly, enabling them to be printable, lightweight, compact, and flexible for use in Internet-of-Things (IoT) devices, such as sensors, antennas, and components in power electronics. However, because electromagnetic waves of all frequency ranges are in the environment, the performance of IoT devices is impacted by interference. For this reason, it can be important to shield sensitive electronic circuits from electromagnetic radiation. For a material to be able to protect against electromagnetic interference (EMI), it should allow minimum transmission through, with the majority of the EMI either absorbed or reflected. However, more recently the term of “green” shielding materials emerged as protection of the external environment from the secondary reflection. Typical materials used for EMI shielding (EMI-SH) are metallic materials due to their excellent metallic conductivity and electromagnetic absorption properties. They have traditionally been applied in bulk geometry (e.g., sheet metals) or a foam coating (e.g., electroplating metals). However, the bulk form tends to be dense and heavy whereas a foam coating is susceptible to the surrounding environment (e.g., physical damage). There is increasing interest in EMI-SH efficiency in conjunction with decreasing the required amount of material, such as the potential for two-dimensional MXene and graphene sheet materials, carbon nanotubes, and metal nanostructures.

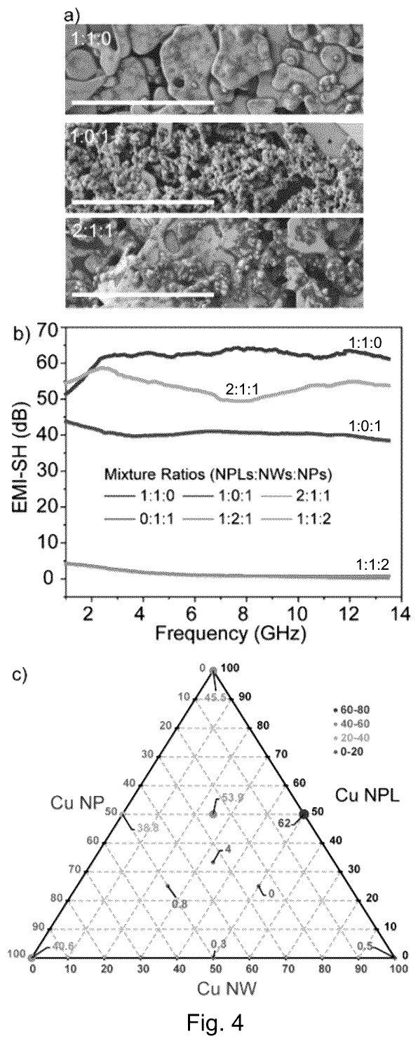

To utilize high conductivity of metals, copper has shown great promise as an EMI-SH material. However, it has been mainly used in bulk geometry, resulting in a dense and thick form. The present disclosure provides the use of printable metal features to alleviate these challenges by utilizing nanoscale materials in producing flexible and lightweight copper conductors. In this disclosure, we report the relationship between the EMI-SH efficiency and printed copper nanostructures. The geometry of Cu nanostructures from nanoparticles (NPs) to nanowires (NWs) and nanoplates (NPLs) can play an important role in controlling the EMI-SH efficiency. For example, printed Cu NPLs can result in a layer stack for improved electromagnetic wave reflection and absorption. In embodiments where multiple Cu nanostructures were mixed, those having greater than 50 wt % of Cu NPLs were shown to have high EMI-SH efficiencies. In addition, the conductivity vs EMI-SH efficiency was observed with an increase in EMI-SH up to 1 MS/m, a diminished increase to 2 MS/m, and plateauing past 2 MS/m at around 55 dB. The Cu nanostructure-dependent EMI-SH efficiencies were plotted into a ternary diagram (see FIG. 4(c)) to provide a pathway toward the printable EMI-SH systems.

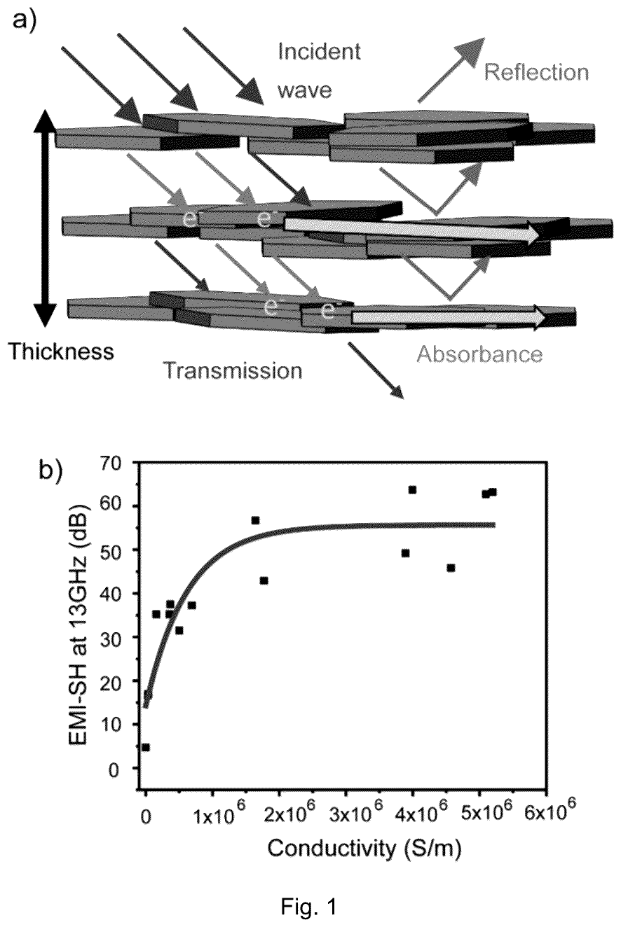

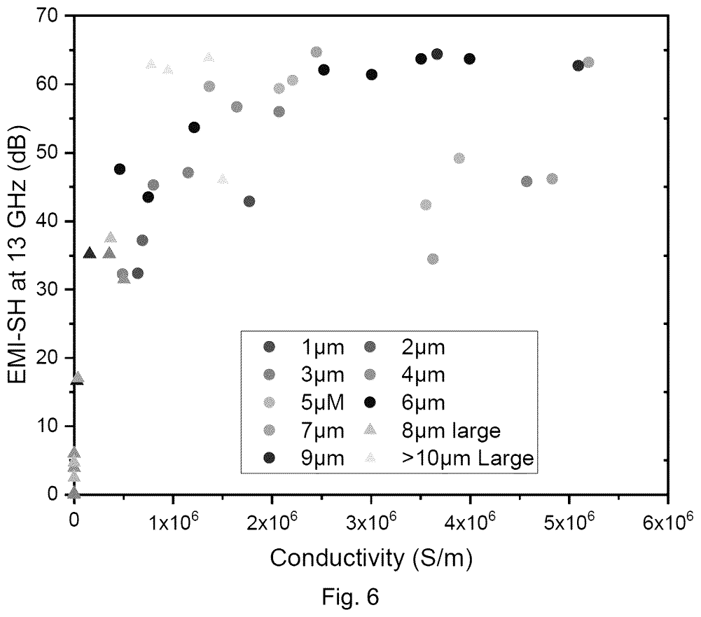

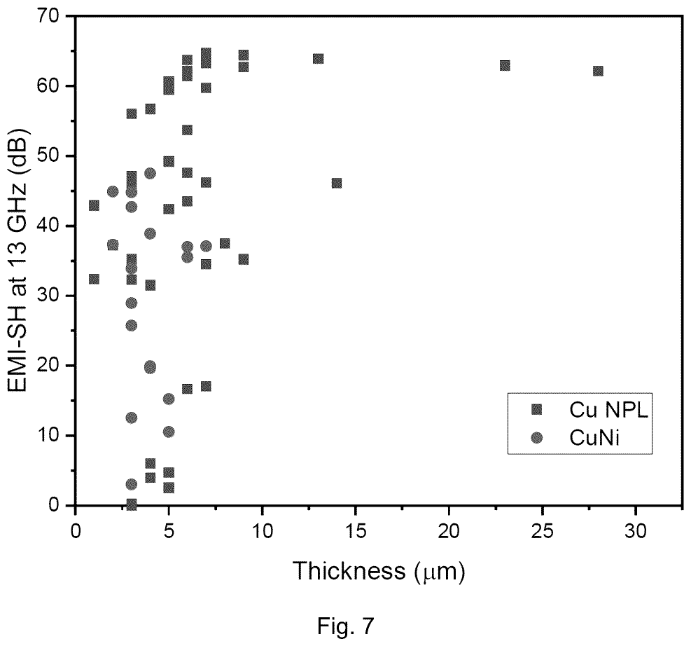

Determining EMI-SH efficiency depends on the interaction between the incident wave's interaction with the materials. The possible interactions, or lack thereof, are reflection, absorbance, or transmission of the incident wave (FIG. 1a). The reflection and absorption of the wave both result in a decrease in intensity, whereas transmission corresponds to the wave penetrating through the material. FIG. 1b illustrates EMI-SH efficiency as a function of electric conductivity of printed Cu NPL features, suggesting higher conductivity for higher EMI-SH efficiency. A more complete data set is shown in FIG. 6. An increase in EMI-SH occurs as electrical conductivity increases to 1 MS/m, where the value increases with diminishing return from 1 to 2 MS/m. Once conductivity is past 2 MS/m, the EMI-SH value plateaus at ˜55 dB. In addition. FIG. 7 is a graph of EMI-SH vs the thickness of printed Cu, on which no observable trend can be determined. These observations reveal that the EMI-SH efficiency is correlated strongly to electric conductivity of printed Cu features. This observation supports conductivity as a key component to higher EMI-SH efficiency.

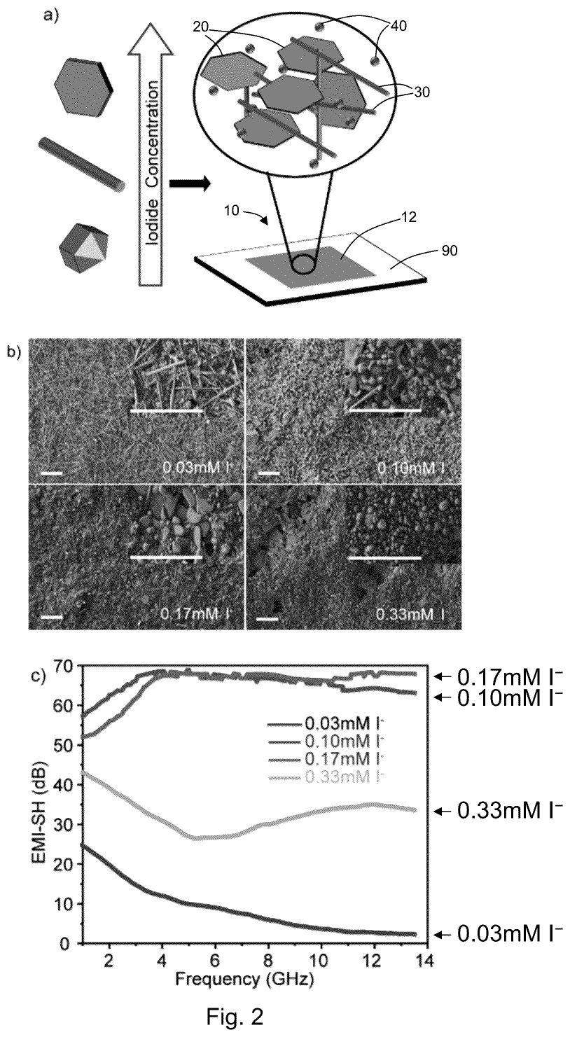

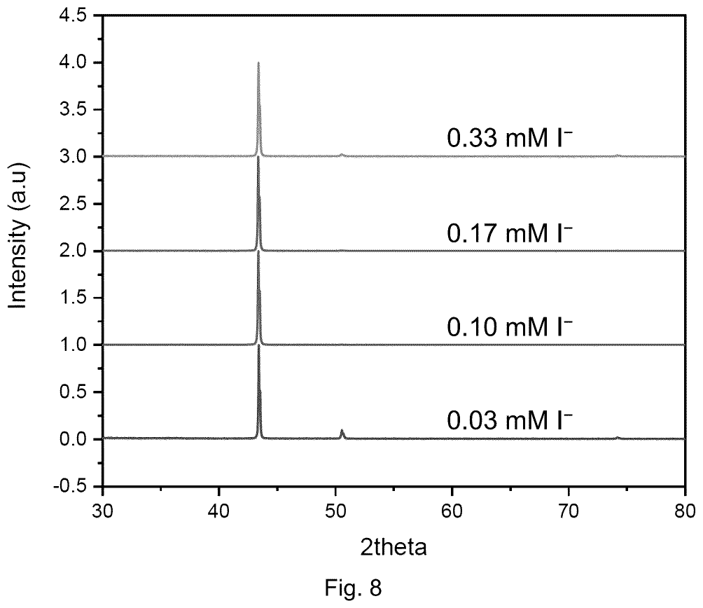

While 2D nanostructures show promise, there is a possibility for gaps to be formed in such printed features. To address this and improve the density of printed Cu conductors, other types of nanostructures (Cu NPs and Cu NWs) can be introduced in the printable ink materials. It should be noted that in the relevant Cu synthesis, the iodide concentration affects the growth kinetics and anisotropy of Cu nanostructures. The following nanostructures can result from the nucleated penta-twinned Cu seeds: Cu NPs. Cu NWs, and Cu NPLs (FIG. 2a). The printed features of Cu nanoplates, nanowires, nanoparticles, or a mixture of all can be further evaluated for the EMI-SH efficiencies. The SEM images (FIG. 2b) are shown for synthesized Cu nanostructures under the iodide concentrations of 0.03. 0.10. 0.17. and 0.33 mM. At a low iodide concentration (0.03 mM), only Cu NWs were observed with no Cu NPLs present. This is expected, as iodide is a key component in forming the Cu nanoplate structure during synthesis. At relatively higher concentrations (0.10 and 0.17 mM I⁻), larger Cu NPLs (around 18 and 20 μm) were observed. These Cu NPLs were larger than the NPLs synthesized with 0.33 mM I⁻ (10 μm). However, at higher concentrations of iodide. NPs were more abundant throughout. These observations were consistent with reported results. The samples with advantageous EMI-SH efficiencies of 60-70 dB are shown in the printed features with the large lateral dimension of Cu NPLs with 20 μm (FIG. 2c). Additionally, the printed Cu features with the lateral dimension of NPLs below 10 μm show an EMI-SH efficiency at around 30-40 dB. The Cu print with the least amount of iodine (0.03 mM) resulted with the lowest EMI-SH efficiency. These observations would suggest that (1) Cu NWs provide low EMI-SH efficiency and (2) larger Cu NPLs would provide higher EMI-SH. However, when compared to previous observations (FIG. 1b), the difference in EMI-SH efficiencies relates to the conductivity of printed Cu features. Table 1 provides the conductivity values and supports the observations shown in FIG. 1b: Printed Cu features made from 0.10 and 0.17 mM I⁻ have a higher electrical conductivity due to the large size of Cu NPLs. The XRD diffractogram (FIG. 8) of the printed Cu features shows mainly the Cu (111) peak present. However, Cu nanostructures made under both 0.03 and 0.33 mM I⁻ also show the presence of Cu (200). The clear dominance in the Cu (111) peak suggests mainly Cu NPLs, but the presence of other peaks suggests either the Cu NWs or Cu NPs were in relevant amounts. Through these observations, it is shown that larger Cu NPLs may play an important role in EMI-SH, while the change in the Cu nanostructure shape could impact the EMI-SH efficiencies of printed features.

TABLE 1
Conductivity values for the printed Cu samples
synthesized at different iodide concentration

| Iodide concentration | |
|---|---|
| (mM) | Conductivity (S/m) |
| 0.03 | Unconductive |
| 0.10 | 5.44E+06 |
| 0.17 | 5.56E+06 |
| 0.33 | 7.34E+05 |

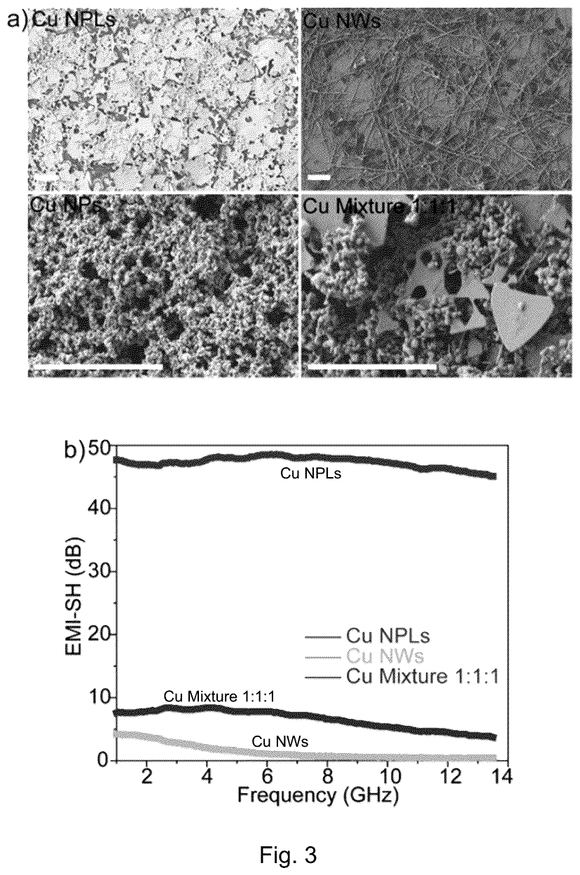

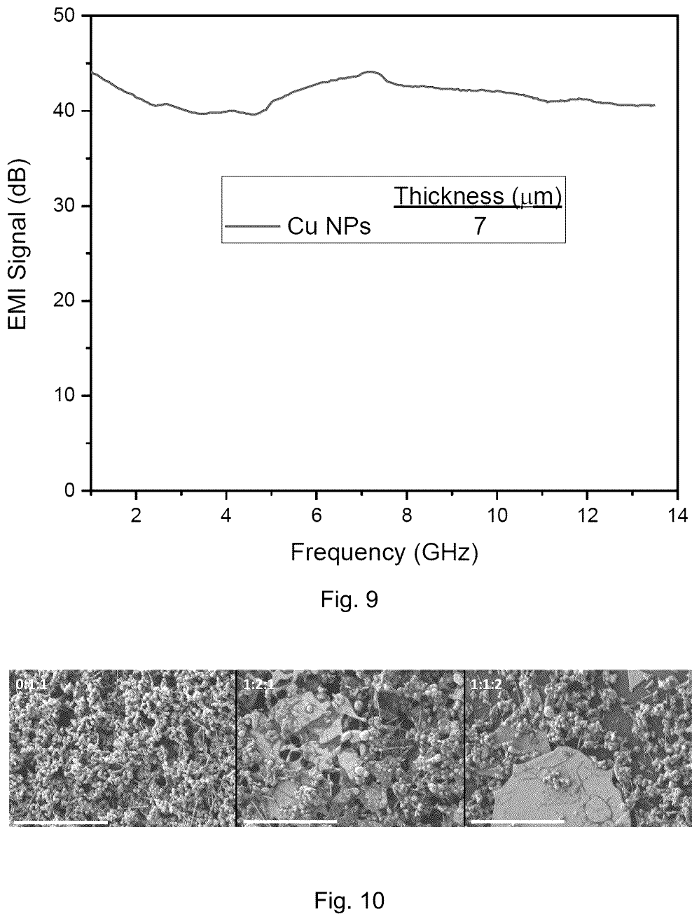

Based on the previous observation, a further investigation into the different Cu nanostructures was conducted. Three different types of Cu nanostructures were synthesized for comparison (the detailed synthetic conditions are shown in the Experimental Section below): Cu NPLs (FIG. 3a, top left), Cu NWs (FIG. 3a, top right), and Cu NPs (FIG. 3a, bottom left). Additionally, the structures were mixed at a 1:1:1 (NPLs:NWs:NPs) ratio (FIG. 3a, bottom right). FIG. 3b shows the EMI-SH efficiencies of printed features from Cu NPLs, Cu NWs, and the 1:1:1 mix with an average thickness of 3 μm. In samples having only one nanostructure, Cu NPLs have a relatively high EMI-SH efficiency (around 50 and 40 dB, respectively), whereas Cu NWs have a lower efficiency (<5 dB throughout). This observation is due to efficient packing and percolation of the Cu NPL in the printed features. However, while Cu NWs are percolated, this resulted in printed features with gaps allowing a majority of the electromagnetic waves through. When mixed at a 1-to-1-to-1 ratio, a low EMI-SH efficiency was also shown but higher than that of Cu NWs alone (5-10 dB). The addition of Cu NPLs (and Cu NPs) to Cu NWs provided slightly higher EMI-SH. The EMI-SH of Cu NPs was similar to that of Cu NPLs (FIG. 9); however, the thickness of Cu NP features was measured to be greater than twice that of Cu NPLs (7 vs 3 μm). The similar EMI-SH but thinner sample of Cu NPLs when compared to Cu NPs, would suggest that Cu NPLs are more efficient at EMI-SH. These observations above suggest that Cu NPLs are an effective nanostructure at both percolation and packing, which is necessary for higher EMI-SH efficiencies.

The investigation was further expanded to more complex ratios of nanostructure mixtures to provide a complete picture of the mixture's effect on the EMI-SH performance. The SEM images are shown in FIG. 4a and FIG. 10. Comparing the EMI-SH of the various mixtures (FIG. 4b), printed features with 50 wt % of Cu NPLs (1:1:0, FIG. 4a, top; 1:0:1, FIG. 4a, middle: and 2:1:1. FIG. 4a. bottom) have higher EMI-SH efficiencies. On the other hand, printed features with <50 wt % of Cu NPLs (0): 1:1, 1:2:1, and 1:1:2; FIG. 10) show low EMI-SH efficiencies. The mixtures with low EMI-SH are overlapped on each other with EMI-SH below 5 dB. When plotting the EMI-SH data at 13 GHZ in a ternary plot (FIG. 4c), a general trend can be observed. When mixing two mixtures, the mixtures with Cu NPLs (1:1:0) and 1:0): 1) have higher efficiencies, but the mixture of Cu NP and Cu NW (0:1:1) have low EMI-SH efficiency. When the mixture included all three nanostructures, the only mixture with notable EMI-SH contained 50 wt % Cu NPLs (2:1:1). The other two combinations (1:2:1 and 1:1:2) show low EMI-SH efficiencies from 0) to 0.8 dB. This observation supports the previous observation, where Cu NPLs appear to have a more efficient coverage regardless of mixture. The data reinforce the benefits of Cu NPLs for greater EMI-SH efficiencies. However, while Cu NWs have a lower percolation threshold, it has lower EMI-SH than that of Cu NPs. There are two possibilities for this observation: the lower mass content of Cu NWs and the gaps in coverage. As Cu NPLs are both flat and relatively longer than that of Cu NPs, the EMI-SH and coverage would be greater. The previous data further support the idea that the layered architecture of Cu NPLs provides better EMI-SH due to an inherently strong absorption of the incident wave and internal reflections more chances for absorption.

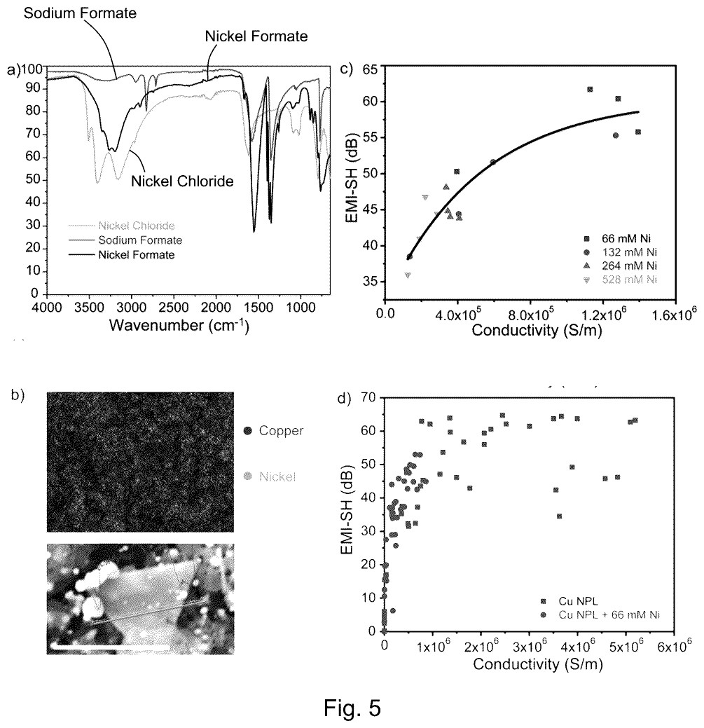

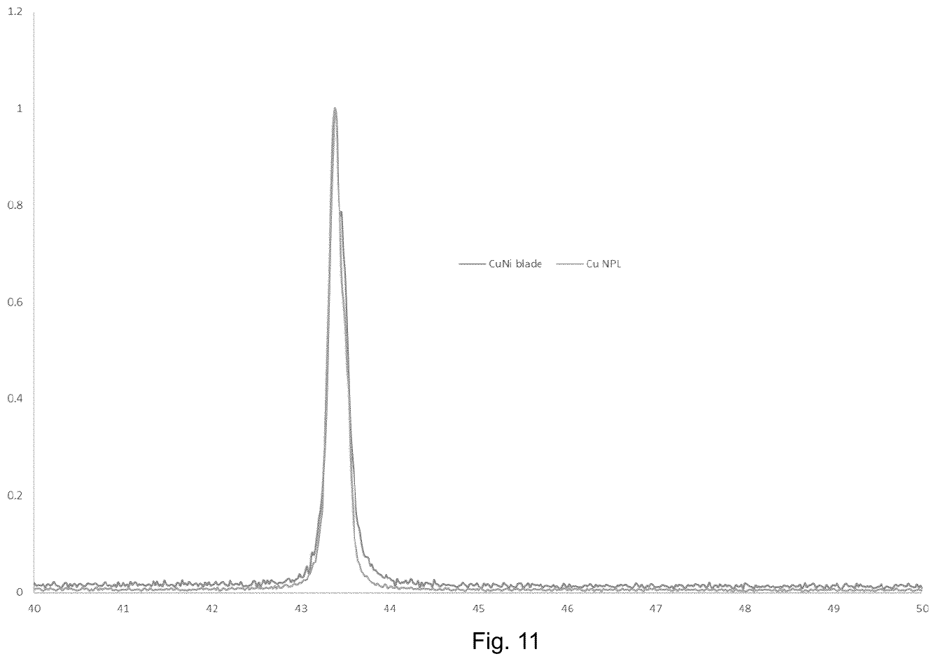

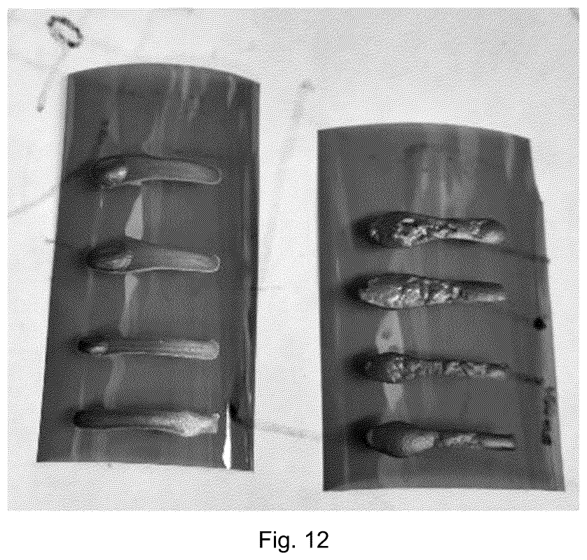

The inclusion of nickel in the sample could influence the EMI-SH for a better reflection of the electromagnetic waves due to its magnetic material nature. The Ni element was included in the printable ink by the preparation of nickel formate (NiF, FIG. 5a). The details of the synthesis and corresponding characterization are described in the Experimental Section below. An EDS mapping and SEM image of a printed Cu/Ni conductor is shown (FIG. 5b). From the EDS mapping (FIG. 5b, top), the copper (red) and nickel (green) are shown to be uniformly distributed throughout the printed conductor. In addition, an EDS line scan (FIG. 5b, bottom) was collected to show a large concentration of Cu with the nickel presence in the conductor. The XRD spectra of printed Cu NPL and Cu/Ni conductors are shown in FIG. 11, on which a slight broadening in the peak supports the presence of nickel. The EMI-SH efficiency dependence as a function of Ni concentration was evaluated and shown in FIG. 5c. The addition of Ni element in the printed features confirms the correlation between electric conductivity and EMI-SH efficiencies (FIG. 12). The ratio of Cu to Ni for each print is shown in Table 2. When the EMI-SH vs conductivity data are overlaid (Cu NPLs alone (squares) vs Cu/Ni NPLs (circles)), an overlap is observed (FIG. 5d), further suggesting the role of Cu NPLs on its EMI-SH efficiencies.

TABLE 2
The EDS data for printed samples at various NiF
concentration added. The Cu and Ni % values
were determined with various other elements.

| Ni concentration | Copper % (in | Nickel % (in | Copper to |
|---|---|---|---|
| added (mM) | EDS spectra) | EDS spectra) | Nickel ratio |
| 66 | 15.88 | 1.85 | 8.58 |
| 132 | 14.67 | 4.06 | 3.61 |
| 164 | 35.74 | 11.91 | 3.00 |
| 528 | 21.77 | 15.45 | 1.41 |

The present disclosure describes the EMI-SH efficiencies of printed Cu features with the control of its electric conductivities and nanostructured geometries, where the EMI-SH efficiencies are investigated against conductivity to determine the correlation between the two. An increase in EMI-SH efficiency is shown with increasing conductivity, with the EMI-SH efficiency of 65 dB plateauing out at conductivity values greater than 2 MS/m. The geometry effect of Cu nanostructures (NPLs, NWs, and NPs) is investigated on the resulting EMI-SH efficiencies, suggesting that Cu NPLs are crucial for high EMI-SH efficiencies as a result from multiple internal reflection and absorption of electromagnetic waves. Lastly, we demonstrate the incorporation of Ni into Cu NPLs and its role for the EMI-SH. The findings presented here provide a guideline into how EMI-SH can be affected by the percolation (electrical conductivity) as well as the geometry of the Cu nanostructures.

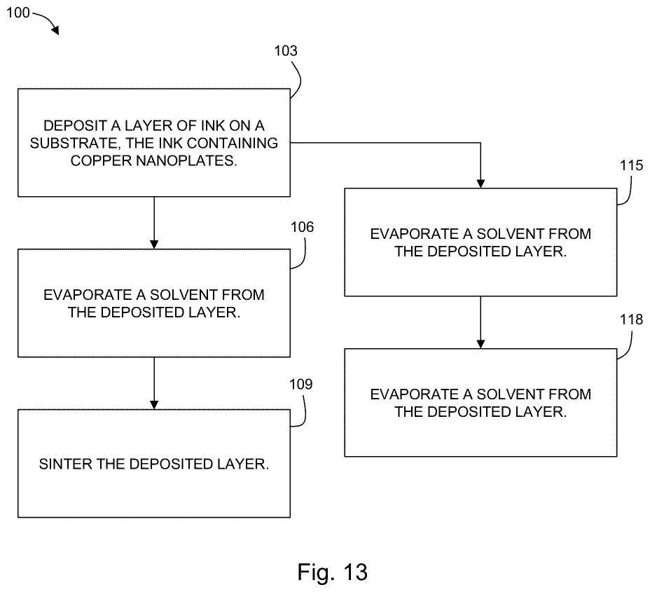

With regard to FIG. 13, in an aspect, the present disclosure provides a method 100 of applying an electromagnetic interference (EMI) shield to a substrate. The substrate may be a flexible substrate, a rigid substrate, or otherwise (combinations, etc.) The method 100 includes depositing 103 a layer of ink onto the substrate, the ink having copper (Cu) nanostructures (e.g., nanoplates, nanowires, or nanoparticles). In embodiments where the ink comprises nanoplates, the ink may further include copper nanowires and/or copper nanoparticles. Depositing 103 the ink may include, for example, extruding 115 the ink using a nozzle and spreading 118 the ink. A solvent (e.g., water, etc.) is evaporated 106 from the deposited layer. The deposited layer is sintered 109 to form an EMI shield. The sintering may use a forming gas (e.g., argon, hydrogen, etc, and combinations). For example, sintering may be done in a forming gas environment.

In some embodiments, the ink further includes a hydroxypropyl methylcellulose (HPMC) solution and water. In some embodiments, the ink further includes a nickel formate solution. For example, the nickel formate solution comprises ethylenediamine (EDA) and water.

In some embodiments, the deposited layer may have a thickness of at least 50 μm. In various embodiments, the deposited layer has a thickness of at least 10 μm, 20 μm, 30 μm, 40 μm, or 60 μm.

In another aspect, the present disclosure provides an electromagnetic interference (EMI) shield 10 including a layer 12 of sintered copper nanoplates 20 (see, for example, FIG. 2 (a)). The EMI shield 10 may be applied to a substrate 90. The EMI shield layer 12 may further include copper nanowires 30 and/or copper nanoparticles 40. For example, the layer may be made up of at least 50 wt % of copper nanoplates. The EMI shield layer may further include nickel. The layer may have a thickness of at least 2 μm, for example, between 2 μm and 10 μm, inclusive (e.g., 2, 3, 4, 5, 6, 7, 8, 9, 10 μm or any value therebetween). In some embodiments, the layer has a conductivity of at least 1 MS/m (for example, 2 MS/m or more).

The substrate may be selected based on the intended application of the EMI shield. Suitable substrates include, but are not limited to, printed circuit boards (PCBs), flexible circuits, electronic device housings, and other surfaces in need of EMI shielding.

The ink for depositing the EMI shield includes copper nanostructures suspended in a suitable solvent. The solvent can be an organic solvent, water-based solvent, or a mixture of solvents that allow for proper dispersion and adhesion of the copper nanostructures.

The ink layer is deposited onto the substrate using a suitable deposition method, such as screen printing, inkjet printing, spray coating, or other known techniques. The deposition process may ensure a uniform distribution of the copper nanoplates across the substrate's surface, creating a continuous conductive layer that will form the basis of the EMI shield.

After deposition, the solvent present in the ink layer is evaporated. The solvent evaporation can be achieved through methods such as natural drying, forced-air drying, etc.

The deposited layer is sintered to create an EMI shield on the substrate—for example, a continuous EMI shield. The sintering process may involve heating the deposited layer to a temperature below the melting point of the copper nanoplates but high enough to cause the nanoplates to fuse and form a solid, conductive layer. The sintering temperature and duration can vary depending on the specific ink formulation and substrate material. The sintering process can be performed using various methods, including convection heating, infrared heating, or microwave heating.

### EXPERIMENTAL SECTION

The following are non-limiting examples of steps, materials, and quantities used in experimental embodiments.

Materials. Glucose, CuBr, CuSO₄, nickel chloride, formic acid, hexadecylamine (HAD), and polyvinylpyrrolidone (PVP) were acquired from VWR. Sodium iodide and (hydroxypropyl) methyl cellulose were acquired from Sigma-Aldrich. Diethylene glycol, hexadecylamine, and copper (II) chloride dihydrate were acquired from Beantown Chemical.

Sodium hypophosphite anhydrous was acquired from JT Baker. Ethanol was acquired from Decon Laboratories, Inc. All chemicals were used as acquired.

Synthesis of Cu NPLs. The synthesis included combining copper chloride dihydrate (CuCl₂·2H₂O, 2.4 g; 14.1 mmol; 15.7 mM), D-glucose (C₆H₁₂O_{6, 3.9} g; 21.6 mmol; 24 mM), hexadecylamine (HDA, 14.55 g; 60.2 mmol; 66.9 mM), and sodium iodide (NaI, 90 mg; 0.6 mmol; 0.54 mM) with 900 mL of DI water. This solution was mixed using a blender for about 3 minutes to obtain a uniform emulsion. 600 mL of the above solution was heated in an autoclavable glass bottle for 12 hours at 100° C. The Cu NPL solids were collected via centrifugation at 5000 rpm for 5 min. The solids obtained from centrifugation were then redispersed in DI H₂O and filtered with a 180 μm membrane to remove any material left bigger than said membrane. Finally, the Cu NPLs were centrifuged to collect the solids and further cleaned with the addition of DI H₂O and ethanol at a 1:1 ratio, and then the ink feedstock was collected via centrifugation. For the larger synthesis of Cu NPLs, copper bromide (CuBr, 2.02 g; 14.1 mmol; 15.7 mM) was used instead of CuCl₂. The synthetic procedure and cleaning procedure were the same as above.

Synthesis of Cu NWs. The synthesis process of Cu NWs was the same as Cu NPLs, without the addition of sodium iodide. When synthesizing the NWs, the reaction was cut short to 9 h (instead of 12 h) at 100° C. The cleaning procedure the same cleaning procedure was followed as above.

Synthesis of Cu NPs. The synthesis of Cu NPs was adapted from the literature. Briefly, CuSO₄ (10 g) and water (50 mL) were mixed until CuSO₄ had been completely dissolved. At the same time, a reactor with polyvinylpyrrolidone (PVP; 12 g), sodium hypophosphite (NaH₂PO₂ H₂O; 3.717 g), and diethylene glycol (150 mL) was stirred and heated at 140° C., to dissolve the PVP and NaH₂PO₂·H₂O. The solution turned slightly yellow in this time. The solution of CuSO₄ was then added in dropwise until all was added. The solution was then allowed to react for 1 h before pulling it from the heat to cool. The Cu NPs were washed with methanol, and the solids were collected through centrifugation. These Cu NPs were then dried under vacuum and kept as solids until further use.

Preparing NiF and NiF Solution. Nickel chloride was used as the nickel salt and was dissolved in water. The formic acid was then added to the nickel chloride solution. The molar ratio of nickel chloride to formic acid was 1:2. This mixture was heated to ˜60° C., to promote the synthesis. After a few minutes, the color of the solution changed. The solution was allowed to cool, and solids were precipitated out from the solution. The solids were then collected via vacuum filtration and washed with additional ethanol, before drying in air. To prepare the NiF solution, the solids were dissolved in solution. To promote solubility, ethylenediamine (EDA) was used at a 2:1 ratio to NiF. First, EDA was added to water. NiF was then added and mixed until fully dissolved. The final molarity of NiF in the solution was 1 M.

Preparation of Cu (Ni) Ink. After the ink feedstock was obtained, hydroxypropyl methylcellulose (HPMC) solution (2 wt % in DI H2O), DI H₂O, and Cu semisolid feedstock (Cu NPLs, Cu NWs, or Cu NPs) were mixed together to make a conductive ink. The total ink weight includes the conductive filler (25 wt %), HPMC solution (20 wt %), and additional water (55 wt %). The resulting mass content for each ink was about 6 wt %, 1 wt %. and 20 wt % of copper for NPL, NWs, and NPs, respectively. This mixture was then mixed in the Thinky Mixer (ARE-310) to achieve a homogeneous ink. Direct writing through Voltera V-One and doctor-blading were utilized for printing the conductive inks. The ink is printed via extrusion method where the conductive ink is forced out through the nozzle onto the substrate.

The ink printed through doctor-blading was spread to have a wet film thickness of over 50 μm. The substrates used are plastics (Kapton). After printing, the conductor was kept under ambient conditions, allowing the water to evaporate. Following this, the prints were sintered at 300° C. under forming gas (95% Ar and 5% H₂). This process promotes contact and removal of residual organics on the surface. To prepare the Cu/Ni ink, the NiF solution was added in the Cu NPL ink. This mixture was then further mixed in the Thinky Mixer to thoroughly mix the ink. The printing and sintering processes were the same as above.

Characterization. The scanning electron microscopy (SEM) image energy-dispersive X-ray spectroscopy (EDS) spectra were collected on a Carl Zeiss AURIGA Crossbeam. The electrical conductivity was collected with an Ossilla four-point probe. The Xray diffraction patterns were obtained with a Rigaku Ultima IV with a Cu source and an operational X-ray tube power of 1.76 KW. FTIR spectra were collected with by an Agilent Cary 630 FTIR.

EMI-SH Testing. The EMI shielding measurements were performed using a Shielding Effectiveness Test Fixture (EM-2108) from Electro Metrics. The test equipment includes two connected probes with a shared passage and can be opened for enabling the sample placement. One of the probes harbors the receiving antenna while the other has the transmitting antenna. The transmitting antenna transmits a set of RF waves at a specific frequency, and the receiving antenna records all of the electromagnetic signals received.

The steps of the method described in the various embodiments and examples disclosed herein are sufficient to carry out the methods of the present invention. Thus, in some embodiments, the method consists essentially of a combination of the steps of the methods disclosed herein. In other embodiments, the method consists of such steps.

Although the present disclosure has been described with respect to one or more particular embodiments, it will be understood that other embodiments of the present disclosure may be made without departing from the spirit and scope of the present disclosure.

What is claimed is:

1. A method of applying an electromagnetic interference (EMI) shield to a substrate, comprising:
depositing a layer of ink onto the substrate, the ink comprising copper (Cu) nanoplates and a solvent;
evaporating the solvent from the deposited layer; and
sintering the deposited layer to form an EMI shield.

2. The method of claim 1, wherein the solvent is water.

3. The method of claim 2, wherein the ink further comprises hydroxypropyl methylcellulose (HPMC).

4. The method of claim 3, wherein the ink further comprises a nickel formate solution.

5. The method of claim 4, wherein the nickel formate solution comprises ethylenediamine (EDA) and water.

6. The method of claim 1, wherein depositing the layer comprises:
extruding the ink through a nozzle; and
spreading the ink on the substrate.

7. The method of claim 1, wherein the deposited layer has a thickness of at least 50 μm.

8. The method of claim 1, wherein the substrate is flexible.

9. The method of claim 1, wherein the sintering uses a forming gas.

10. The method of claim 1, wherein the ink further comprises copper nanoparticles, copper nanowires, or both.

11. The method of claim 10, wherein the copper nanoplates make up between 1 and 30 wt %, inclusive.

12. The method of claim 1, wherein the ink composition is such that the resulting EMI shield has a conductivity of at least 1 MS/m.

13. The method of claim 1, wherein the EMI shield has a thickness of at least 2 μm, for example, between 2 μm and 10 μm, inclusive.

14. An electromagnetic interference (EMI) shield, comprising a layer of sintered copper nanoplates.

15. The EMI shield of claim 14, wherein the layer further comprises copper nanowires and/or copper nanoparticles.

16. The EMI shield of claim 15, wherein the copper nanoplates comprise at least 50 wt % of the layer.

17. The EMI shield of claim 14, wherein the layer further comprises nickel.

18. The EMI shield of claim 14, wherein the layer has a thickness of at least 2 μm.

19. The EMI shield of claim 14, wherein the layer has a conductivity of at least 1 MS/m.
